(19) United States
(12) Patent Application Publication
(10) Pub. No.: US 2020/0212298 A1
(43) Pub. Date: Jul. 2, 2020

(54) Self-Aligned Magnetic Metal Shield to Enhance the Coercivity of STT-MRAM Devices

(71) Applicant: Headway Technologies, Inc., Milpitas, CA (US)

(72) Inventors: Yi Yang, Fremont, CA (US); Guenole Jan, San Jose, CA (US); Yu-Jen Wang, San Jose, CA (US)

(21) Appl. No.: 16/236,740

(22) Filed: Dec. 31, 2018

(51) Int. Cl. H01L 43/12; H01L 43/02; H01L 43/10

(52) U.S. Cl. CPC H01L 43/12; H01L 27/222; H01L 43/10; H01L 43/02

(57) ABSTRACT

A MTJ stack is deposited on a bottom electrode, the stack comprising at least a pinned layer, a barrier layer, a free layer, and a top electrode layer. The top electrode and MTJ stack are etched where not covered by a photoresist pattern to form an MTJ structure. A conformal encapsulation dielectric is deposited over the MTJ structure. A magnetic metal layer is deposited on the encapsulation dielectric and anisotropically etched leaving a magnetic metal shield on sidewalls of the MTJ structure. A dielectric layer is deposited over the magnetic metal shield and MTJ structure. The dielectric layer and encapsulation dielectric are polished away to expose the top electrode. A top metal contact layer is deposited contacting the top electrode and the magnetic metal shield wherein the magnetic metal shield has no contact with said bottom electrode and MTJ structure but is separated from them by the encapsulation dielectric.

### TECHNICAL FIELD

This application relates to the general field of magnetic tunneling junctions (MTJ) and, more particularly, to methods for preventing shorts and sidewall damage in the fabrication of MTJ structures.

### BACKGROUND

Spin transfer torque magnetic random access memory (STT-MRAM) is a strong candidate for future memory applications. In magnetic tunnel junctions (MTJ), the free layer, which stores information for the memory bit, has two preferred magnetization orientations that are perpendicular to the physical plane of the layer. The free layer magnetization direction is expected to be maintained during a read operation and idle, but to change to the opposite direction during a write operation if the new information to store differs from its current memory state. The ability to maintain free layer magnetization direction during an idle period is called data retention or thermal stability. It is proportional to the product of the coercivity (Hc) and the free layer's magnetic moment where Hc is the minimum magnetic field needed to reverse the FL magnetization direction. For embedded STT-MRAM, the MTJ must be able to withstand annealing temperatures up to about 400° C. for 30 minutes which are typical of back end of line (BEOL) semiconductor processes. However, this high temperature procedure usually degrades both the Hc and the magnetic moment. A new MTJ device structure which is capable of enhancing the Hc is needed to better integrate this type of magnetic memory to Complementary Metal-Oxide-Semiconductor (CMOS) technologies.

Several patents teach metal surrounding an MTJ structure, including U.S. Pat. No. 10,084,127 (Annunziata et al), U.S. Pat. No. 10,096,768 (Jiang et al), and U.S. Pat. No. 6,929,957, but these methods are different from the present disclosure.

### SUMMARY

It is a primary object of the present disclosure to provide a method of enhancing coercivity in the fabrication of a MTJ structure without affecting other device performance parameters.

Another object of the present disclosure is to provide a method of forming a magnetic metal shield surrounding a MTJ structure to enhance coercivity of the MTJ without affecting other device performance parameters.

In accordance with the objectives of the present disclosure, a method for fabricating a magnetic tunneling junction (MTJ) structure is achieved. A MTJ stack is deposited on a bottom electrode, the stack comprising at least a pinned layer, a barrier layer on the pinned layer, and a free layer on the barrier layer. A top electrode layer is deposited on the MTJ stack. The top electrode and MTJ stack are etched where not covered by a photoresist pattern to form an MTJ structure. A conformal encapsulation dielectric is deposited over the MTJ structure. Thereafter, a magnetic metal layer is deposited on the encapsulation dielectric. The magnetic metal layer is anisotropically etched leaving a magnetic metal shield on sidewalls of the MTJ structure. A dielectric layer is deposited over the magnetic metal shield and MTJ structure. The dielectric layer and encapsulation dielectric are polished away to expose the top electrode. A top metal contact layer is deposited contacting the top electrode and the magnetic metal shield wherein the magnetic metal shield has no contact with said bottom electrode and MTJ structure but is separated from them by the encapsulation dielectric.

Also in accordance with the objectives of the present disclosure, a magnetic tunneling junction (MTJ) structure comprises a pinned layer on a bottom electrode, and a barrier layer on the pinned layer, a free layer on the barrier layer, and a top electrode on the free layer. Dielectric sidewalls on the pinned layer, barrier layer, free layer, and top electrode separate them from a vertical magnetic metal shield. The dielectric sidewalls also separate the bottom electrode horizontally from the magnetic metal shield. A top magnetic metal shield is formed horizontally on the top electrode and contacting the vertical magnetic metal shield.

### BRIEF DESCRIPTION OF THE DRAWINGS

In the accompanying drawings forming a material part of this description, there is shown:

FIGS. 1 through 6 illustrate in cross-sectional representation steps in a first preferred embodiment of the present disclosure.

FIGS. 7 through 11 illustrate in cross-sectional representation steps in a second preferred embodiment of the present disclosure.

FIG. 12A is a cross-sectional representation of the free layer and magnetic shield of the present disclosure when no external magnetic field is applied.

FIG. 12B is a top view of the free layer and magnetic shield of the present disclosure when no external magnetic field is applied.

FIG. 13A is a cross-sectional representation of the free layer and magnetic shield of the present disclosure when a external magnetic field is applied.

FIG. 13B is a top view of the free layer and magnetic shield of the present disclosure when a external magnetic field is applied.

### DETAILED DESCRIPTION

In a typical process, patterned MTJ structures are separated from one another simply by the insulating encapsulation and dielectric materials. Therefore, coercivity (Hc) is determined by the materials within the MTJ stack. In the present disclosure, we form a magnetic metal shield surrounding the MTJ structure which can increase the device's “effective” Hc by reducing the external magnetic field. All other device parameters remain the same.

In the process of the present disclosure, using a self-aligned dielectric hard mask, we form a magnetic metal shield surrounding the MTJ. This metal shield is not in contact with the MTJ and the bottom electrode, but is separated from them by the insulating encapsulation material. Since the external magnetic field through the free layer is compensated by the field generated by the shield, the minimum required magnetic field needed to switch the free layer's magnetization direction is increased; i.e., enhancing the device's “effective” Hc. Compared to the traditional way of re-designing different materials in the MTJ stack to increase Hc, the method in the present disclosure is simple, only involving several additional metal/dielectric deposition and plasma etch steps. Moreover, the method to define the magnetic metal is a self-aligned process which does not require the complicated and expensive lithography, overlay, and CD control which becomes particularly challenging when the device size goes down to sub 60 nm.

The present disclosure describes two methods of fabricating the magnetic metal shield. The first method is illustrated in FIGS. 1-6 and the second method is illustrated in FIGS. 1-3 and 7-11.

The first preferred embodiment of the present disclosure will be described in more detail with reference to FIGS. 1-6. FIG. 1 illustrates a bottom electrode layer 12 formed on a semiconductor substrate, not shown. Now, the MTJ stack, comprising at least a seed layer 14, a pinned layer 16, a tunnel barrier layer 18, and a free layer 20, is deposited on the bottom electrode. A top electrode 22 comprising Ta, TaN, Ti, TiN, W, Cu, Mg, Ru, Cr, Co, Fe, Ni or their alloys is deposited over the MTJ stack to a thickness h1 of 10-100 nm, and preferably 50 nm. A dielectric hard mask 24 of SiO₂, SiN, SiON, SiC or SiCN is deposited onto the top electrode to a thickness of 20 nm. Finally a photoresist mask 26 is formed over the hard mask 24 forming pillar patterns with size ˜70-80 nm and height 200 nm for etching the MTJ stack.

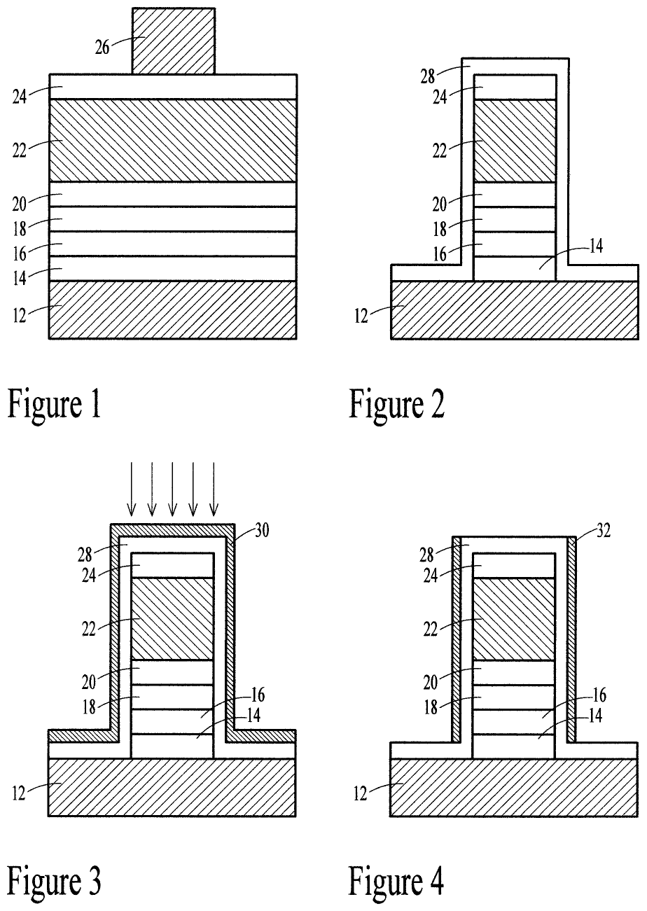

The dielectric hard mask and top electrode are then etched by fluorine carbon based plasma such as CF₄ or CHF₃ alone, or mixed with Ar and N₂ or physical RIE or IBE. The MTJ is then completely etched, either by chemical RIE, physical RIE or IBE, or their combination with a pattern size of ˜60 nm or below, as shown in FIG. 2. An encapsulation material 28 made of dielectric materials such as SiN, SiC, SiCN, carbon, TaC, Al₂O₃ or MgO with thickness of 5-30 nm, is either in-situ or ex-situ conformally deposited by chemical vapor deposition (CVD), physical vapor deposition (PVD), or atomic layer deposition (ALD) onto the MTJ patterns.

Now, as shown in FIG. 3, a magnetic metal shield 30 which consists of one or multiple layers of magnetic metals such as Co, CoFeB, or NiFe, or their combination is deposited onto the encapsulated MTJ patterns. Next, an anisotropic etch process is performed to pattern the metal shield directly. No further photolithography is performed. For example, RIE with large bias power of between about 100 and 1000 watts and low source power of between about 0 and 100 watts or an IBE process, at a 0° angle with respect to the normal line of the patterns' horizontal surface, is used. Due to the much larger vertical etch rate than horizontal, the metal layer on the patterns' top and bottom regions is removed, leaving the metal shield 32 only on the sidewalls of the MTJ structures, separated from them by the dielectric encapsulation layer 28, as shown in FIG. 4. It is important to note that the remaining metal shield has no contact with the bottom electrode and MTJ but is separated from them by the encapsulation material 28. Therefore, this metal shield does not cause an electrical short.

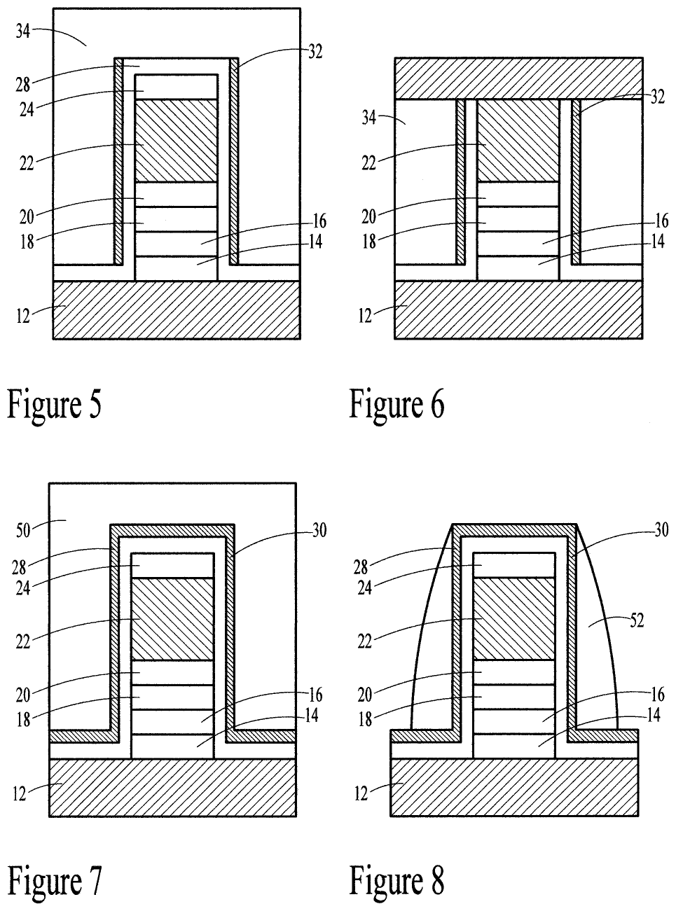

Referring now to FIG. 5, a dielectric layer 34 is deposited over the encapsulated MTJ and metal shield. A chemical mechanical polishing (CMP) process is performed to expose the top electrode 22. As shown in FIG. 6, a magnetic top metal contact 36, which can be the same or different from the sidewall shield materials, is deposited. As a result, the free layer is thus surrounded by the magnetic shields vertically 32 and horizontally 36. The external magnetic field through the free layer is reduced by these sidewall and top metal shields, which increases the device's “effective” Hc.

The second preferred embodiment of the present disclosure will be described in more detail with reference to FIGS. 1-3 and 7-11. Processing is the same as in the first embodiment through the FIG. 3 deposition of the metal shield material 30. This alternative embodiment has a larger process margin. As shown in FIG. 7, a dielectric or metal oxide spacer 50 is deposited, either in-situ or ex-situ, by chemical vapor deposition (CVD), physical vapor deposition (PVD), or atomic layer deposition (ALD). As shown in FIG. 8, the portion of the spacer on top and bottom of the patterns is then etched away by RIE or IBE, exposing the metal shield 30 underneath. However, the spacer 52 on the sidewall is partially reserved because of the larger vertical etch rate than horizontal.

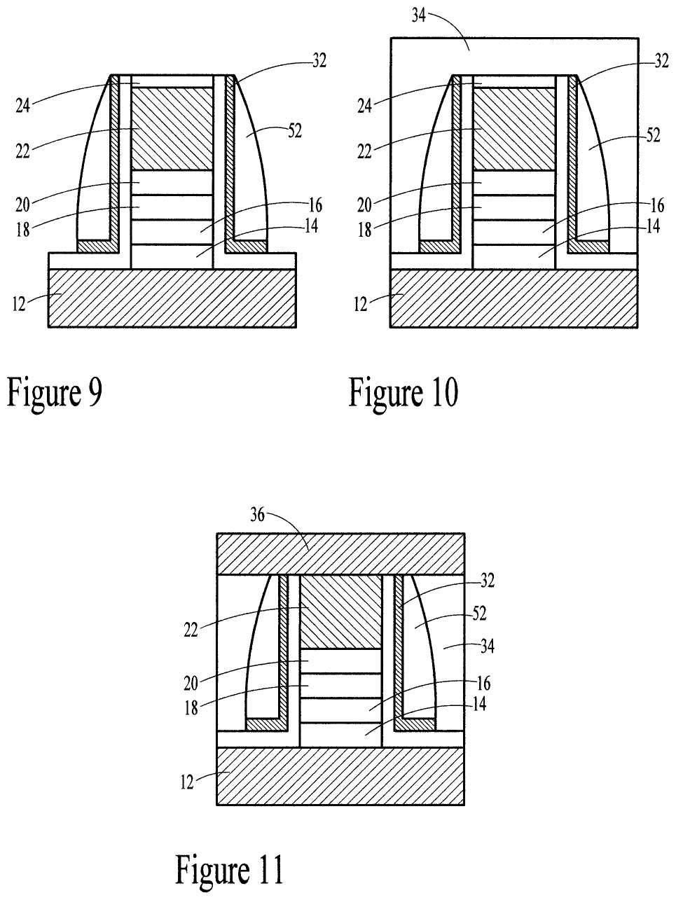

Now, using the sidewall spacer 52 as a self-aligned hard mask, the portion of the metal shield 30 on the top and bottom of the patterns is etched away, either by RIE, IBE or their combination, only leaving the metal shield 32 on the sidewall as protected by the spacer 52 as illustrated in FIG. 9. No photolithography is performed in these patterning processes.

Referring now to FIG. 10, a dielectric layer 34 is deposited over the encapsulated MTJ and metal shield. CMP is performed to expose the top electrode 22. As shown in FIG. 11, a magnetic top metal contact 36, which can be the same or different from the sidewall shield materials, is deposited. As a result, the free layer is thus surrounded by the magnetic shields vertically 32 and horizontally 36. The external magnetic field through the free layer is reduced by these sidewall and top metal shields, which increases the device's “effective” Hc.

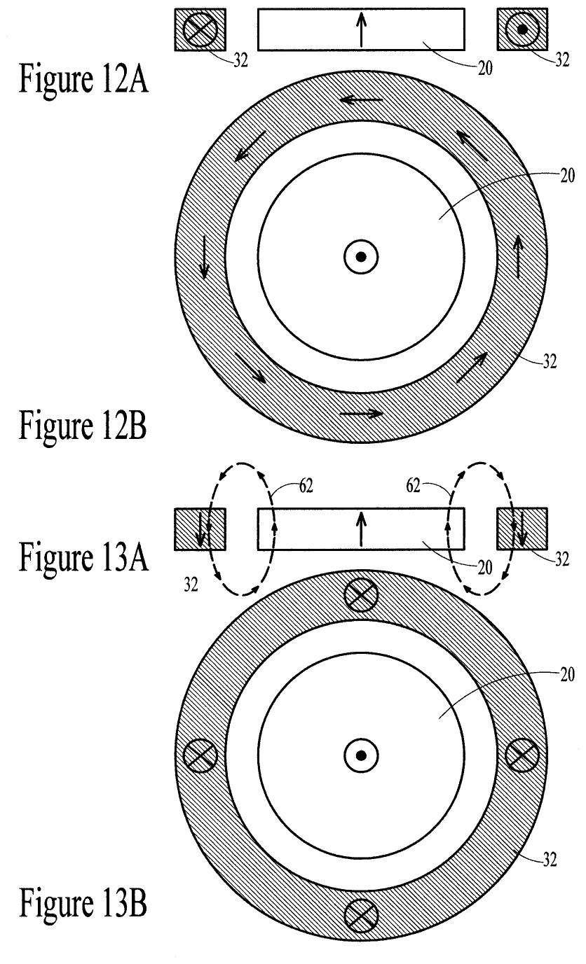

FIGS. 12 and 13 describe the principle of tailoring the anisotropy of the shield so that the magnetization remains in plane when no magnetic field is applied and rotates out of plane upon an externally applied field. Ideally the field generated by the shield is engineered to compensate for the applied magnetic field. FIGS. 12A and 12B illustrate the case where no external magnetic field is applied. FIG. 12A shows a cross-sectional view of the free layer 20 and the surrounding metal shield 32, while FIG. 12B shows a top view of the free layer and surrounding metal shield.

FIG. 13A shows a cross-sectional view of the free layer 20 and the surrounding metal shield 32, while FIG. 13B shows a top view of the free layer and surrounding metal shield. When an external magnetic field 60 is applied, the magnetization of the shield rotates out of plane and starts to apply a field 62 on the MTJ that is opposite to the external field applied.

In the process of the present disclosure, we increase the STT-MRAM's Hc by forming a magnetic metal shield surrounding the MTJ. All other device parameters are not affected by this method. The process of the present disclosure is especially useful for embedded STT-MRAM chips, the Hc of which is challenging to maintain during the 400° C. back end of line (BEOL) fabrication and post annealing steps. The metal shield fabrication methods of the present disclosure, using direct anisotropic etching or self-aligned dielectric spacer etching, are simpler and more precise than expensive lithography methods. Furthermore, the disclosed methods avoid increasing overlay and CD control challenges of the lithography processes with device scaling.

Although the preferred embodiment of the present disclosure has been illustrated, and that form has been described in detail, it will be readily understood by those skilled in the art that various modifications may be made therein without departing from the spirit of the disclosure or from the scope of the appended claims.

What is claimed is:

1. A method for fabricating a magnetic tunneling junction (MTJ) structure comprising:
depositing a MTJ stack on a bottom electrode;
depositing a top electrode layer on said MTJ stack;
etching said top electrode and MTJ stack not covered by a photoresist pattern to form a MTJ structure;
depositing a conformal encapsulation dielectric over said MTJ structure;
thereafter depositing a magnetic metal layer on said encapsulation dielectric;
thereafter anisotropically etching said magnetic metal layer leaving a magnetic metal shield on sidewalls of said MTJ structure;
depositing a dielectric layer over said magnetic metal shield and said MTJ structure;
polishing away said dielectric layer and said encapsulation dielectric to expose said top electrode; and
forming a top metal contact layer contacting said top electrode and said magnetic metal shield wherein said magnetic metal shield has no contact with said bottom electrode and said MTJ structure but is separated from them by said encapsulation dielectric.

2. The method according to claim 1 wherein said top electrode layer comprises Ta, TaN, Ti, TiN, W, Cu, Mg, Ru, Cr, Co, Fe, Ni or their alloys having a thickness of 10-100 nm, and preferably ≥50 nm.

3. The method according to claim 1 further comprising a dielectric hard mask on said top electrode wherein said dielectric hard mask comprises SiO₂, SiN, SiON, SiC or SiCN having a thickness of ≥20 nm.

4. The method according to claim 3 wherein said dielectric hard mask and top electrode are etched by fluorine carbon based plasma such as CF₄ or CHF₃ alone, or mixed with Ar and N₂ or physical reactive ion etching (RIE) or ion beam etching (IBE) prior to etching said MTJ stack.

5. The method according to claim 1 wherein said MTJ stack is etched by chemical RIE, physical RIE, or IBE.

6. The method according to claim 1 wherein said encapsulation dielectric comprises SiN, SiC, SiCN, carbon, TaC, Al₂O₃ or MgO and is in-situ or ex-situ deposited by chemical vapor deposition (CVD), physical vapor deposition (PVD), or atomic layer deposition (ALD) to a thickness of 5-30 nm.

7. The method according to claim 1 wherein said magnetic metal layer comprises one or multiple layers of magnetic metals comprising one or more of Co, CoFeB and NiFe.

8. The method according to claim 1 wherein said anisotropically etching said magnetic metal layer comprises:
reactive ion etching with a bias power of between 100 and 1000 watts and a source power of between about 0 and 100 watts; or
ion beam etching at a 0° angle with respect to a normal line to horizontal surfaces of said MTJ structure.

9. The method according to claim 1 wherein said anisotropically etching said magnetic metal layer comprises:
depositing a dielectric or metal oxide spacer material, either in-situ or ex-situ, by chemical vapor deposition (CVD), physical vapor deposition (PVD), or atomic layer deposition (ALD) over said magnetic metal layer;
etching away said spacer material on horizontal surfaces of said magnetic metal layer to leave said spacer material on vertical surfaces of said magnetic metal layer; and
thereafter performing RIE or IBE to etch away said magnetic metal layer not covered by said spacer material.

10. The method according to claim 1 wherein a free layer of said MTJ structure is surrounded by a magnetic shield vertically by said magnetic metal shield and horizontally by said top metal contact layer and wherein an external magnetic field applied through said free layer is reduced by surrounding said magnetic shield and wherein an effective coercivity is thereby increased.

11. A method for fabricating a magnetic tunneling junction (MTJ) structure comprising:
depositing a MTJ stack on a bottom electrode wherein said MTJ stack comprises at least a seed layer, a pinned layer on said seed layer, a barrier layer on said pinned layer, and a free layer on said barrier layer;
depositing a top electrode layer on said MTJ stack;
depositing a dielectric hard mask on said top electrode layer;
etching said dielectric hard mask and said top electrode not covered by a photoresist pattern to form a hard mask;
etching said MTJ stack not covered by said hard mask to form an MTJ structure;
depositing a conformal encapsulation dielectric over said MTJ structure;
thereafter depositing a magnetic metal layer on said encapsulation dielectric;
thereafter anisotropically etching said magnetic metal layer leaving a magnetic metal shield on sidewalls of said MTJ structure;
depositing a dielectric layer over said magnetic metal shield and said MTJ structure;
polishing away said dielectric layer and said encapsulation dielectric to expose said top electrode; and
forming a top metal contact layer contacting said top electrode and said magnetic metal shield wherein said magnetic metal shield has no contact with said bottom electrode and said MTJ structure but is separated from them by said encapsulation dielectric, wherein an external magnetic field applied through said free layer is reduced by surrounding said magnetic metal shield and wherein an effective coercivity is thereby increased.

12. The method according to claim 11 wherein said top electrode layer comprises Ta, TaN, Ti, TiN, W, Cu, Mg, Ru, Cr, Co, Fe, Ni or their alloys having a thickness of 10-100 nm, and preferably ≥50 nm.

13. The method according to claim 11 wherein said dielectric hard mask comprises SiO₂, SiN, SiON, SiC or SiCN having a thickness of ≥20 nm.

14. The method according to claim 11 wherein said dielectric hard mask and top electrode are etched by fluorine carbon based plasma such as CF₄ or CHF₃ alone, or mixed with Ar and N₂ or physical reactive ion etching (RIE) or ion beam etching (IBE) and wherein said MTJ stack is etched by chemical RIE, physical RIE, or IBE.

15. The method according to claim 11 wherein said encapsulation dielectric comprises SiN, SiC, SiCN, carbon, TaC, Al₂O₃ or MgO and is in-situ or ex-situ deposited by chemical vapor deposition (CVD), physical vapor deposition (PVD), or atomic layer deposition (ALD) to a thickness of 5-30 nm.

16. The method according to claim 11 wherein said magnetic metal layer comprises one or multiple layers of magnetic metals comprising one or more of Co, CoFeB and NiFe.

17. The method according to claim 11 wherein said anisotropically etching said magnetic metal layer comprises:
reactive ion etching with a bias power of between 100 and 1000 watts and a source power of between about 0 and 100 watts; or
ion beam etching at a 0° angle with respect to a normal line to horizontal surfaces of said MTJ structure.

18. The method according to claim 11 wherein said anisotropically etching said magnetic metal layer comprises:
depositing a dielectric or metal oxide spacer material, either in-situ or ex-situ, by chemical vapor deposition (CVD), physical vapor deposition (PVD), or atomic layer deposition (ALD) over said magnetic metal layer;
etching away said spacer material on horizontal surfaces of said magnetic metal layer to leave said spacer material forming on vertical surfaces of said magnetic metal layer; and
thereafter performing RIE or IBE to etch away said magnetic metal layer not covered by said spacer material.

19. A magnetic tunneling junction (MTJ) comprising:
a pinned layer on a bottom electrode;
a barrier layer on said pinned layer;
a free layer on said barrier layer;
a top electrode on said free layer;
dielectric sidewalls on said pinned layer, barrier layer, free layer, and top electrode; and
a magnetic metal shield on said dielectric sidewalls and on top of said top electrode wherein said magnetic metal shield is separated vertically from said free layer by said dielectric sidewalls and horizontally from said bottom electrode by said dielectric sidewalls.

20. The MTJ according to claim 18 wherein an external magnetic field applied through said free layer is reduced by surrounding said magnetic metal shield and wherein an effective coercivity is thereby increased.
